(19) United States
(12) Patent Application Publication
(10) Pub. No.: US 2002/0039811 A1
(43) Pub. Date: Apr. 4, 2002

(54) A method of manufacturing a semiconductor device

(76) Inventor: Atsushi Fujisawa, Hakodate (JP)

Correspondence Address: Mattingly Stanger & Malur P.C., Suite 370, 1800 Diagonal Road, Alexandria, VA, 22314, US

(21) Appl. No.: 09/934,651

(22) Filed: Aug. 23, 2001

(30) Foreign Application Priority Data
Sep. 29, 2000 (JP) 2000-298941

(51) Int. Cl. H01L 21/44; H01L 21/48; H01L 21/50

(52) U.S. Cl. 438/127; 438/612; 438/460

(57) ABSTRACT

A semiconductor device comprising: a tape substrates 2 for supporting a semiconductor chip 1; wires 4 for connecting the pads of the semiconductor chip 1 and the connection terminals of the tape substrates 2; a sealing portion formed on the chip supporting face 2a of the tape substrates 2 for resin-sealing the semiconductor chip 1; and a plurality of solder balls disposed on the back face 2b of the tape substrates 2. After a block molding operation for resin-molding a plurality of device areas altogether, the semiconductor device is diced and individualized. By performing the block-molding operation using a molding tool having protrusions 13c on a cavity forming face 13a, grooves 8a are formed in the surface of a block-molded portion 8 when this portion 8 is formed. Therefore, the tensile deformation of the surface of the block-molded portion 8 at the setting/shrinking time of a molding resin 14 is relaxed by the grooves 8a to reduce the warpage of the block-molded portion 8 after the resin was set.

### FIELD OF THE INVENTION

The present invention relates to a semiconductor manufacturing technique and, more particularly, to a technique which is effective when applied to improvements in the yield and quality of the semiconductor device.

### BACKGROUND OF THE INVENTION

A semiconductor device (or a semiconductor package), as provided with a semiconductor chip having a semiconductor integrated circuit formed therein, is known through examples of this art such as the CSP (Chip Scale Package) or the BGA (Ball Grid Array) which is provided with bump electrodes (e.g., solder balls) as external terminals and a chip supporting substrate for supporting the semiconductor chip.

Of these, the CSP is made so small and thin as is slightly larger than the chip size or the semiconductor chip. The CSP has been developed to have a structure in which the semiconductor chip is mounted on one face of the chip supporting substrate, i.e., on a chip supporting face and in which the chip supporting face side is resin-sealed by a molding operation to form a sealed portion.

Considering the thinness, the heat resistance and the adhesion to the molding resin, therefore, a flexible tape substrate of a thin film made of a polyimide base material is frequently used as the aforementioned chip supporting substrate.

Moreover, the block-molding method has been devised as the technique for improving the production efficiency of the CSP, which is manufactured by using the tape substrate made of a polyimide base material, to lower the cost.

The aforementioned block-molding method uses a multi-device substrate which has been formed to have a plurality of device areas corresponding to the tape substrate defined in dividing area, and resin-seals the multi-device substrate by a molding method with the plurality of device areas individually having the semiconductor chips being covered altogether, thereby to form a block-sealed portion. After this resin-sealing operation, the multi-device substrate and the block-sealed portion are diced and divided (or individualized) at the unit of device areas.

Here, the semiconductor package to be assembled by using the block-molding method and the method of manufacturing the semiconductor package are described in Japanese Patent Laid-Open No. 2000-12745, for example.

### SUMMARY OF THE INVENTION

In the aforementioned block-molding method, however, the plurality of device areas are molded altogether so that the block-sealed portion formed has a large area and is made relatively thin. Especially when a flexible substrate is adopted, a warpage occurs in the block-sealed portion.

When the solder balls (or the bump electrodes) are mounted at the assembling step after the molding operation or when the tape substrates are cut, therefore, there arise problems of a displacement or a cracking of the sealed portion or the like.

Therefore, a technique for avoiding the warpage is essential for the block-sealed portion formed by the block-molding operation. In the aforementioned Japanese Patent Laid-Open No. 2000-12745, however, there is neither description on the warpage of the block-sealed portion formed to have a large area formed by the block-molding operation or on the countermeasure against the warpage so that no consideration is taken into the warpage of the block-sealed portion.

An object of the invention is to provide a semiconductor device manufacturing method for improving the yield and lowering the cost by reducing the warpage of the block-sealed portion.

On the other hand, another object of the invention is to provide a manufacturing method of a semiconductor device for improving the quality.

The aforementioned and other objects and the novel features of the invention will become apparent from the following description to be made with reference to the accompanying drawings.

The representative ones of the invention to be disclosed herein will be briefly summarized in the following.

According to the invention, more specifically, there is provided a method of manufacturing a resin-sealed type semiconductor device, comprising: the step of preparing a chip supporting substrate having a plurality of device areas; the step of mounting a semiconductor chip on said device areas; the step of connecting the surface electrode of said semiconductor chip and the corresponding electrode of said chip supporting substrate through conductive members; the step of covering said plurality of device areas altogether with a cavity, by using a molding tool which is provided with: said cavity for covering said plurality of device areas altogether on the chip supporting face side of said chip supporting substrate; and protrusions on a cavity forming face for forming said cavity; the step of resin-sealing said semiconductor chip by feeding a molding resin to said cavity with said plurality of device areas being covered altogether with said cavity, and forming a block-sealed portion having grooves formed in the surface by said protrusions; and the step of dividing said chip supporting substrate and said block-sealed portion at the unit of said device areas.

According to the invention, the deformation, as caused by the shrinkage of the surface at the setting/shrinking time of the molding resin, can be relaxed to reduce the warpage of the block-sealed portion after the resin was set.

Therefore, the assembly at the manufacturing step after the molding operation can be improved to improve the yield of the semiconductor device and to lower the cost.

According to the invention, on the other hand, there is provided a method of manufacturing a resin-sealed type semiconductor device, comprising: the step of preparing a chip supporting substrate having a plurality of device areas; the step of mounting a semiconductor chip on said device areas; the step of connecting the surface electrode of said semiconductor chip and the corresponding electrode of said chip supporting substrate through conductive members; the step of covering said plurality of device areas altogether with a cavity, by using a molding tool which is provided with: said cavity for covering said plurality of device areas altogether on the chip supporting face side of said chip supporting substrate; and lattice-shaped protrusions corresponding to dicing lines on a cavity forming face for forming said cavity; the step of resin-sealing said semiconductor chip by feeding a molding resin to said cavity with said plurality of device areas being covered altogether with said cavity, and forming a block-sealed portion having grooves at the portions corresponding to the dicing lines of the surface formed in the surface by said protrusions; and the step of dividing said chip supporting substrate and said block-sealed portion along said grooves at the unit of said device areas.

According to the invention, the grooves are formed at the portions corresponding to the dicing lines of the surface of the block-sealed portion when this block-sealed portion is formed, the deformation, as caused by the shrinkage of the surface at the setting/shrinking time of the molding resin, can be relaxed by the grooves to reduce the warpage of the block-sealed portion after the resin was set.

Moreover, the grooves are formed at the portions corresponding to the dicing lines in the block-sealed portion so that the stress to be applied to the block-sealed portion, although warped to some extent, by the pushing force of the blade at the dicing step after the molding operation can be concentrated on the grooves corresponding to the dicing lines. Therefore, it is possible to relax the stress to be applied to the surface of the block-sealed portion and to form the cracks, if any, in the grooves corresponding to the dicing lines.

According to the invention, on the other hand, there is provided a method of manufacturing a resin-sealed type semiconductor device, comprising: the step of preparing a chip supporting substrate having a plurality of device areas; the step of mounting a semiconductor chip on said device areas; the step of connecting the surface electrode of said semiconductor chip and the corresponding electrode of said chip supporting substrate through conductive members; the step of covering said plurality of device areas altogether with a cavity, by using a molding tool which is provided with: said cavity for covering said plurality of device areas altogether on the chip supporting face side of said chip supporting substrate; and dicing lines on a cavity forming face for forming said cavity and a plurality of corresponding protrusions around said dicing lines; the step of resin-sealing said semiconductor chip by feeding a molding resin to said cavity with said plurality of device areas being covered altogether with said cavity, and forming a block-sealed portion having grooves formed at the portions corresponding to the dicing lines of the surface and in the inner area by said protrusions; and the step of dividing said chip supporting substrate and said block-sealed portion along said grooves corresponding to said dicing lines and at the unit of said device areas.

According to the invention, moreover, there is provided a method of manufacturing a resin-sealed type semiconductor device, comprising: the step of preparing a chip supporting substrate having a plurality of device areas; the step of mounting a semiconductor chip on said device areas; the step of connecting the surface electrode of said semiconductor chip and the corresponding electrode of said chip supporting substrate through conductive members; the step of covering said plurality of device areas altogether with a cavity, by using a molding tool which is provided with: said cavity for covering said plurality of device areas altogether on the chip supporting face side of said chip supporting substrate; and lattice-shaped protrusions corresponding to dicing lines of a plurality of kinds of semiconductor device sizes on a cavity forming face for forming said cavity; the step of resin-sealing said semiconductor chip by feeding a molding resin to said cavity with said plurality of device areas being covered altogether with said cavity, and forming a block-sealed portion having grooves at the portions corresponding to the dicing lines, as corresponding to the plurality of kinds of semiconductor device sizes, of the surface, formed by said protrusions; and the step of dividing said chip supporting substrate and said block-sealed portion along said grooves at the portions corresponding to the dicing lines corresponding to the individual semiconductor device sizes at the unit of said device areas.

According to the invention, the grooves corresponding to the dicing lines of the plurality of individual semiconductor device sizes can be formed in the block-sealed portion. Therefore, one molding tool can be used to match the various sizes of the semiconductor devices so that the molding tool can be made common independently of the sizes of the semiconductor devices.

According to the invention, on the other hand, there is provided a method of manufacturing a resin-sealed type semiconductor device, comprising: the step of preparing a chip supporting substrate having a plurality of device areas; the step of mounting a semiconductor chip on said device areas; the step of connecting the surface electrode of said semiconductor chip and the corresponding electrode of said chip supporting substrate through conductive members; the step of covering said plurality of device areas altogether with a cavity, by using a molding tool which is provided with: said cavity for covering said plurality of device areas altogether on the chip supporting face side of said chip supporting substrate; and dicing lines on a cavity forming face for forming said cavity and the corresponding protrusions of a plurality of kinds of heights around said dicing lines; the step of resin-sealing said semiconductor chip by feeding a molding resin to said cavity with said plurality of device areas being covered altogether with said cavity, and forming a block-sealed portion having grooves formed at the portions corresponding to the dicing lines of the surface and in the inner area by said protrusions such that the grooves at the portions corresponding to said dicing lines are made deeper than the grooves in said inner area; and the step of dividing said chip supporting substrate and said block-sealed portion along said grooves corresponding to said dicing lines at the unit of said device areas, and assembling a semiconductor device having the plurality of said grooves in the surface of the sealed portion.

According to the invention, moreover, there is provided a method of manufacturing a resin-sealed type semiconductor device, comprising: the step of preparing a chip supporting substrate having a plurality of device areas; the step of mounting a semiconductor chip on said device areas; the step of connecting the surface electrode of said semiconductor chip and the corresponding electrode of said chip supporting substrate through conductive members; the step of covering said plurality of device areas altogether with a cavity, by using a molding tool which is provided with: said cavity for covering said plurality of device areas altogether on the chip supporting face side of said chip supporting substrate; and lattice-shaped protrusions of two kinds of heights on a rectangular cavity forming face for forming said cavity; the step of resin-sealing said semiconductor chip by feeding a molding resin to said cavity with said plurality of device areas being covered altogether with said cavity, and forming a block-sealed portion having grooves at the portions corresponding to the dicing lines of the rectangular surface and formed in the surface by said protrusions such that the grooves parallel to the width direction are made deeper than the grooves parallel to the length direction; and the step of dividing said chip supporting substrate and said block-sealed portion along grooves of two kinds of depths at the unit of said device areas.

According to the invention, at the portions corresponding to the dicing lines in the rectangular surface of the block-sealed portion, the grooves parallel to the width direction of the rectangle can be made deeper than the grooves in parallel to the length direction. Even in the case of the rectangular block-sealed portion having the surface of a different aspect ratio, therefore, it is possible to reduce the warpage of the block-sealed portion easy to warp in the length direction.

### BRIEF DESCRIPTION OF THE DRAWINGS

Of FIGS. 1A and 1B presenting views showing one example of the structure of a semiconductor device (CSP) to be assembled by a semiconductor device manufacturing method according to an embodiment of the invention, FIG. 1A is a top plan view, and FIG. 1B is a bottom view;

FIG. 2 is a sectional view showing the structure of the CSP shown in FIGS. 1A and 1B;

Of FIGS. 3A and 3B presenting views showing one example of the structure of a chip supporting substrate to be used for manufacturing the CSP shown in FIGS. 1A and 1B, FIG. 3A is a top plan view, and FIG. B an enlarged partial top plan view showing the detailed structure of portion A of FIG. 3A;

FIG. 4 is a manufacturing process flow chart showing one example of the assembling procedure in the manufacture of the CSP shown in FIGS. 1A and 1B;

FIG. 5 is a partial top plan view showing one example of the structure of a frame carrier to be used in the manufacture of the CSP shown in FIGS. 1A and 1B and its assembling method;

FIG. 6 is a partial sectional view showing one example of a die-bonding state in the CSP manufacturing method shown in FIGS. 1A and 1B;

FIG. 7 is a partial sectional view showing one example of a die-bonding state in the CSP manufacturing method shown in FIGS. 1A and 1B;

Of FIGS. 8A and 8B presenting sectional views showing one example of a block-molded state in the CSP manufacturing method shown in FIGS. 1A and 1B, FIG. 8A shows a molding resin filling time, and FIG. 8B shows a resin setting time;

FIG. 9 is a partially enlarged top plan view showing one example of the state of the block-molded frame carrier in the CSP manufacturing method shown in FIGS. 1A and 1B;

FIG. 10 is a side elevation showing one example of the bump-mounted state in the CSP manufacturing method shown in FIGS. 1A and 1B;

Of FIGS. 11A and 11B presenting sectional views showing one example of the dicing state in the CSP manufacturing method shown in FIGS. 1A and 1B, FIG. 1A shows the state before diced, and FIG. 1B shows the state after diced;

FIG. 12 is a top plan view showing a structure of the block-sealed portion of a modification of the block-sealed portion shown in FIGS. 11A and 11B;

FIG. 13 is a top plan view showing a structure of the block-sealed portion of a modification of the block-sealed portion shown in FIGS. 11A and 11B;

FIG. 14 is a sectional view showing a structure of the CSP of a modification of the CSP shown in FIGS. 1A and 1B;

FIG. 15 is a top plan view showing the structure of a block-sealed portion of a modification of the block-sealed portion shown in FIGS. 11A and 11B;

FIG. 16 is a top plan view showing the structure of a block-sealed portion of a modification of the block-sealed portion shown in FIGS. 11A and 11B; and

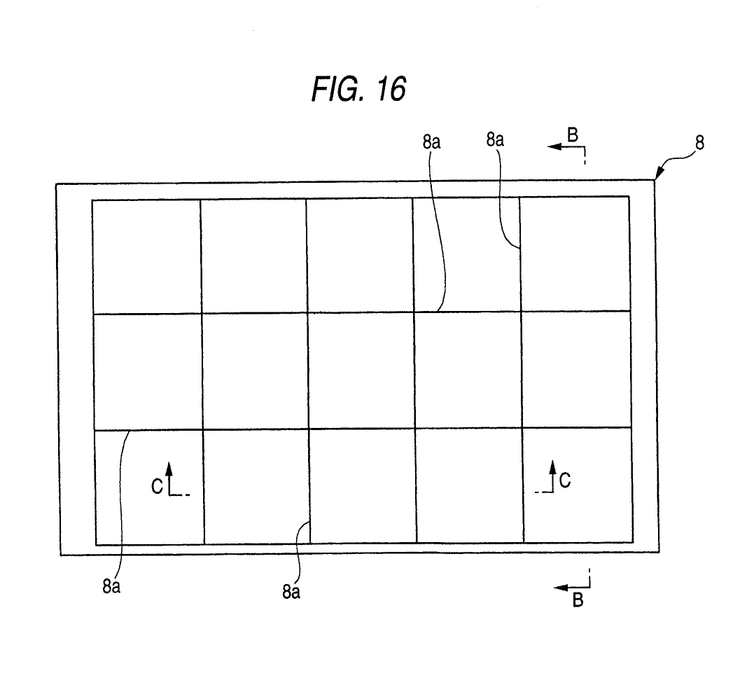

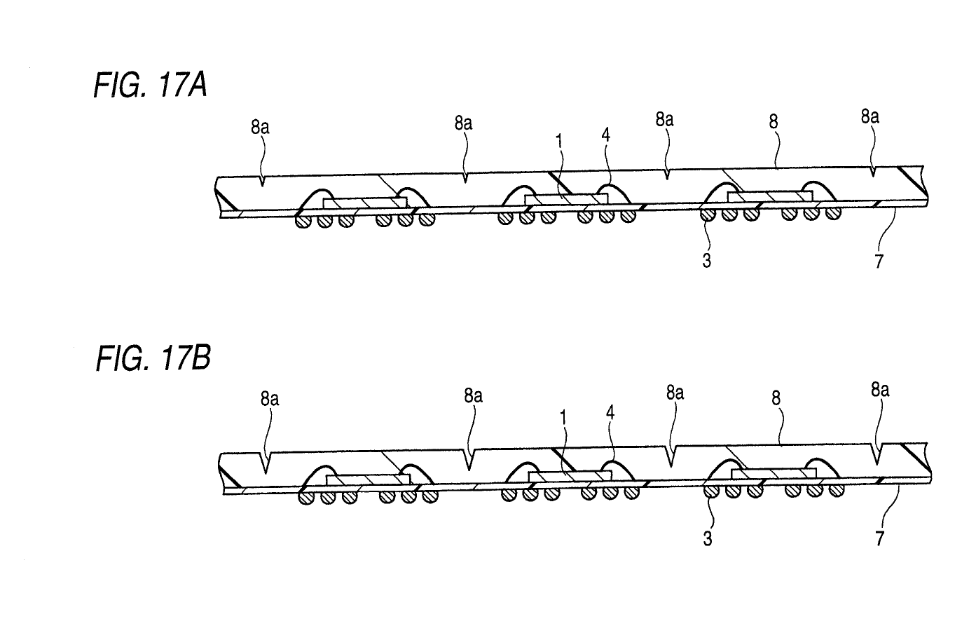

Of FIGS. 17A and 17B presenting partially enlarged sectional views showing the sectional structure of a block-sealed portion of a modification shown in FIG. 16, FIG. 17A is a section taken along line B-B of FIG. 16, and FIG. 17B is a section taken along line C-C of FIG. 16.

### DESCRIPTION OF THE PREFERRED EMBODIMENTS

The embodiments of the invention will be described in detail with reference to the accompanying drawings. Throughout all the Figures for describing the embodiments, the repeated description of members having the same functions will be omitted by designating them by common reference numerals.

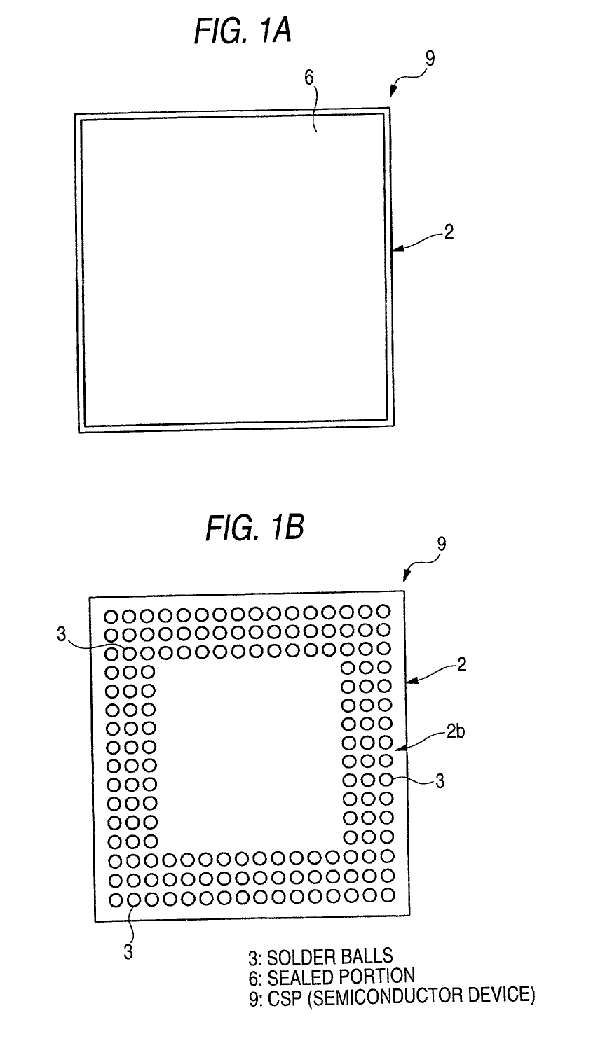

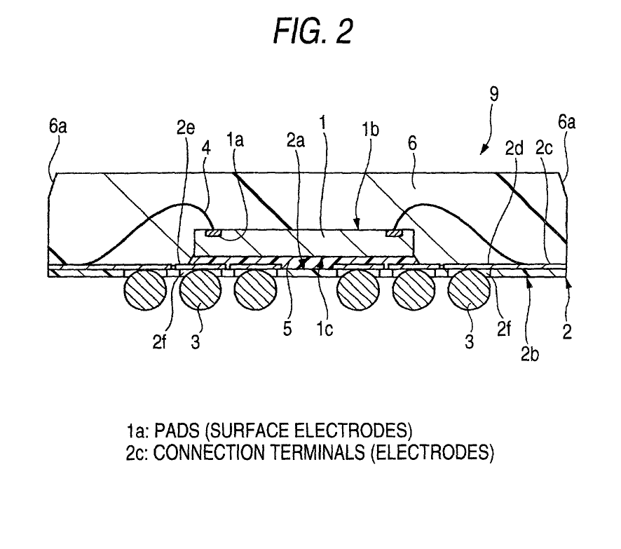

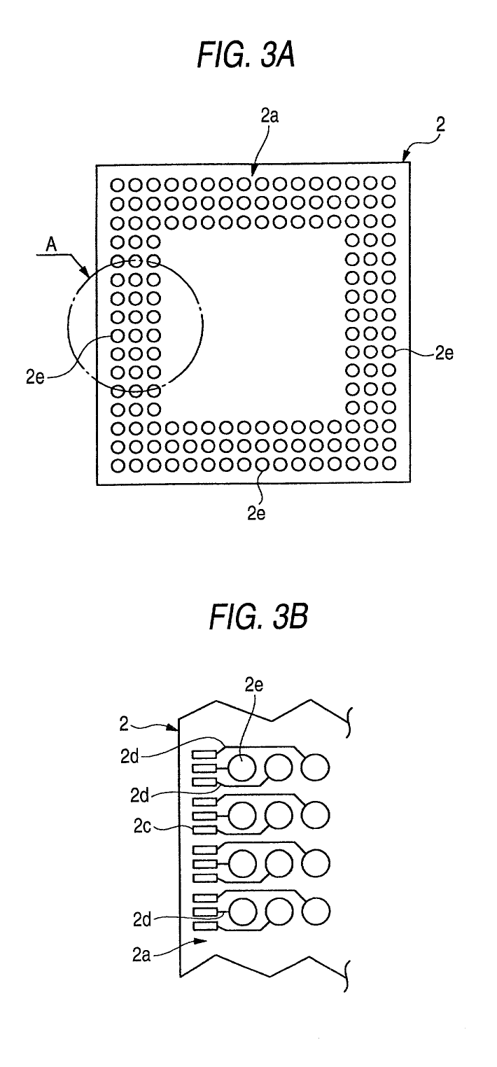

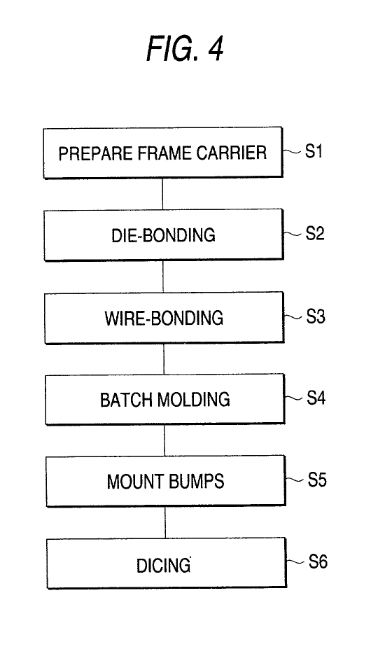

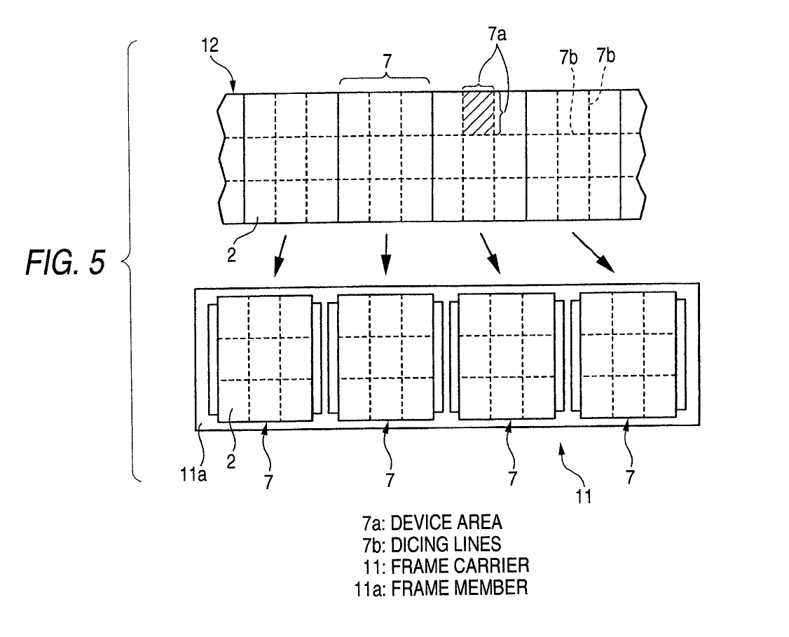

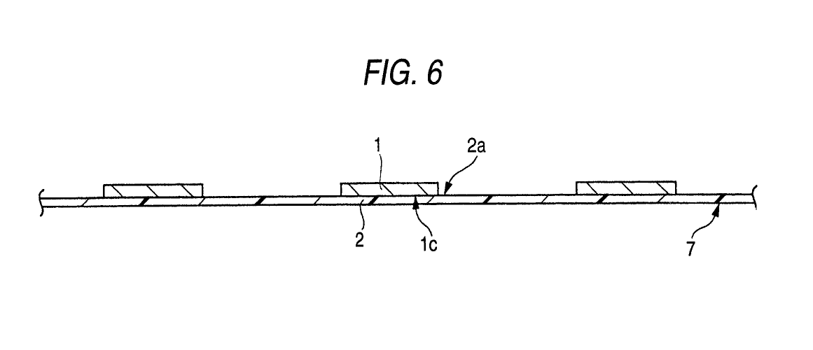

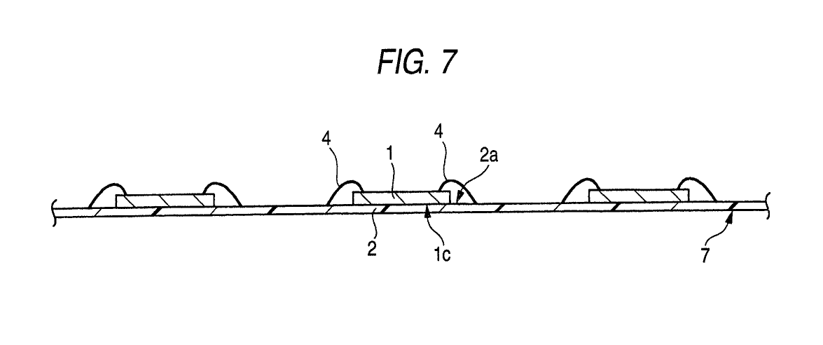

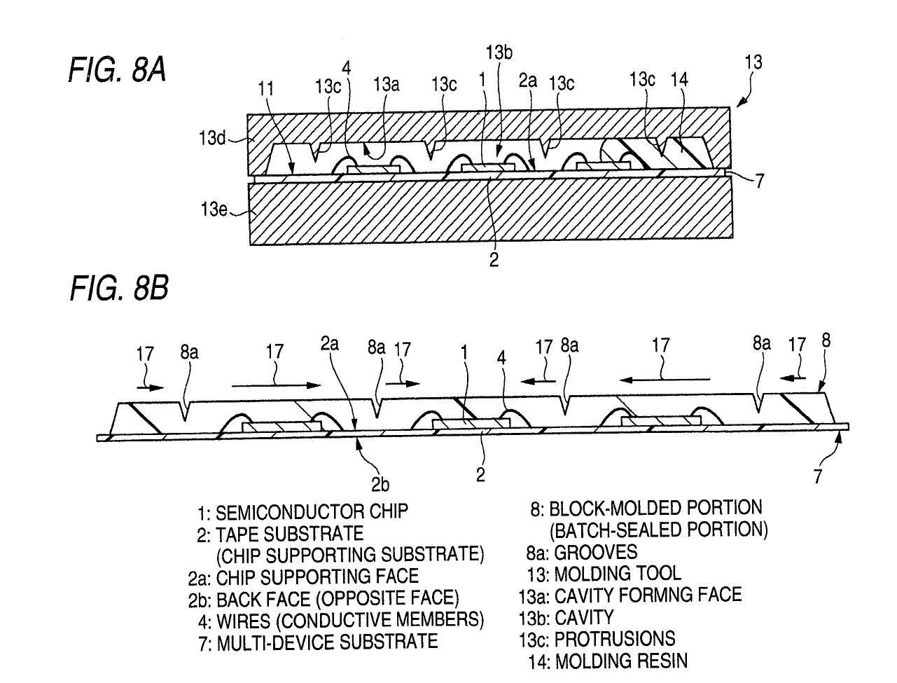

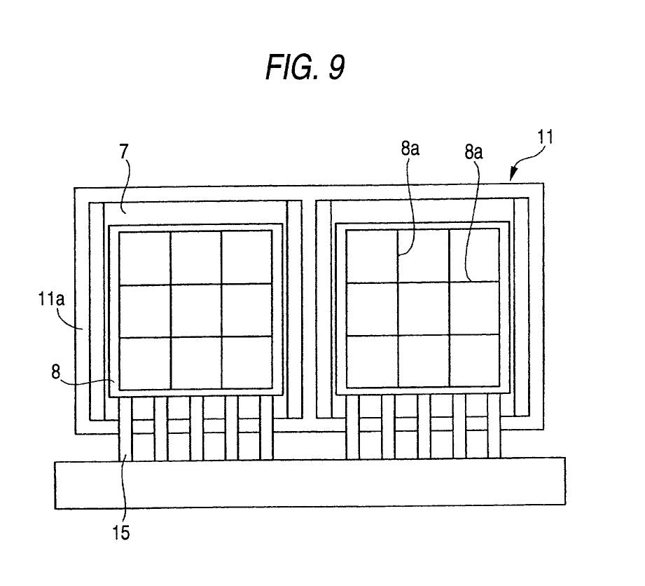

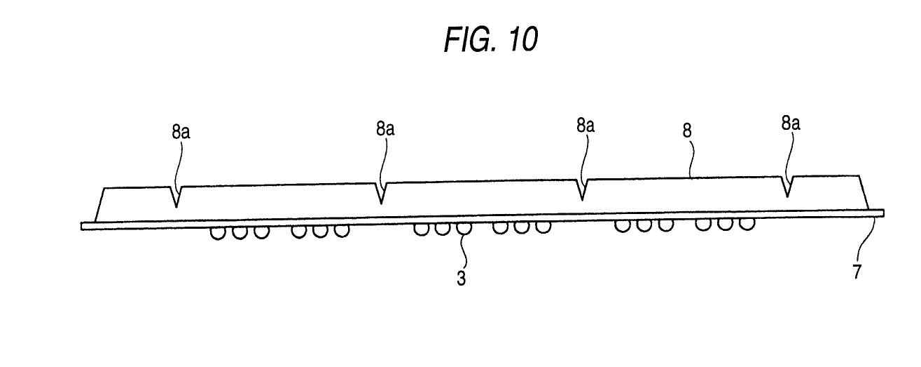

Of FIGS. 1A and 1B presenting views showing one example of the structure of a semiconductor device (CSP) to be assembled by a semiconductor device manufacturing method according to an embodiment of the invention, FIG. 1A is a top plan view, and FIG. 1B is a bottom view; FIG. 2 is a sectional view showing the structure of the CSP shown in FIGS. 1A and 1B; of FIGS. 3A and 3B presenting views showing one example of the structure of a chip supporting substrate to be used for manufacturing the CSP shown in FIGS. 1A and 1B, FIG. 3A is a top plan view, and FIG. B an enlarged partial top plan view showing the detailed structure of portion A of FIG. 3A; FIG. 4 is a manufacturing process flow chart showing one example of the assembling procedure in the manufacture of the CSP shown in FIGS. 1A and 1B; FIG. 5 is a partial top plan view showing one example of the structure of a frame carrier to be used in the manufacture of the CSP shown in FIGS. 1A and 1B and its assembling method; FIG. 6 is a partial sectional view showing one example of a die-bonding state in the CSP manufacturing method shown in FIGS. 1A and 1B; FIG. 7 is a partial sectional view showing one example of a die-bonding state in the CSP manufacturing method shown in FIGS. 1A and 1B; of FIGS. 8A and 8B presenting sectional views showing one example of a block-molded state in the CSP manufacturing method shown in FIGS. 1A and 1B, FIG. 8A shows a molding resin filling time, and FIG. 8B shows a resin setting time; FIG. 9 is a partially enlarged top plan view showing one example of the state of the block-molded frame carrier in the CSP manufacturing method shown in FIGS. 1A and 1B; FIG. 10 is a side elevation showing one example of the bump-mounted state in the CSP manufacturing method shown in FIGS. 1A and 1B; of FIGS. 11A and 11B presenting sectional views showing one example of the dicing state in the CSP manufacturing method shown in FIGS. 1A and 1B, FIG. 1A shows the state before diced, and FIG. 1B shows the state after diced.

In the semiconductor device of this embodiment shown in FIGS. 1A and 1B and FIG. 2, a chip supporting substrate for supporting a semiconductor chip 1 is a tape substrate 2 of a thin film. Here will be described a CSP 9 or a semiconductor package of the size equal to or slightly larger than the chip size, in which the semiconductor chip 1 is resin-sealed by a molding method on the side of a chip supporting face 2a of the tape substrate 2.

On the face (as will be called the “back face 2b”), as opposed to the chip supporting face 2a, of the tape substrate 2, as shown in FIG. 1B and FIG. 2, a plurality of solder balls (or bump electrodes) 3 are arranged as external terminals, except the central portion.

Here, the CSP 9 of this embodiment is prepared by resin-molding (hereafter refereed to as the “block-molding”) with covering a plurality of device areas 7a, defined by dicing lines 7b, in a block-covering manner altogether using a multi-device substrate 7 attached to a frame member 11a of a frame carrier 11, as shown in FIG. 5, and by dicing and individualizing a block-molded portion (or a block-sealed portion) 8 thus formed, as shown in FIGS. 9 and 10, after molded.

Here will be described the structure of the CSP 9. This CSP 9 is constructed to include: the film-shaped tape substrate 2 of a thin film for supporting the semiconductor chip 1; wires (conductive members) 4 for connecting pads 1a or surface electrodes of the semiconductor chip 1 and the corresponding connection terminals (or electrodes) 2c of the tape substrate 2; a sealing portion 6 formed over the chip supporting face 2a of the tape substrate 2 for resin-sealing the semiconductor chip 1 and the wires 4; and the plurality of solder balls 3 or the plurality of bump electrodes disposed as external terminals on the back face 2b of the tape substrate 2.

Here, the CSP 9 is block-molded and is diced and individualized. At this time, on a cavity forming face 13a for forming cavities 13b of a top part 13d of a molding tool 13, as shown in FIG. 8A, there are formed protrusions 13c at portions corresponding to the dicing lines 7b, as shown in FIG. 5, so that grooves 8a shown in FIG. 10 are formed at the molding time in the bath-molded portion 8 by those protrusions 13c. By dicing along the grooves 8a, slopes 6a or portions of the grooves 8a, as shown in FIG. 2, are formed, after the dicing, in the peripheral edge corner portion of the surface of the sealing portion 6.

Here, FIG. 8A shows the case in which the cavity forming face 13a is formed on the top part 13d of the molding tool 13 and in which the protrusions 13c are formed on that cavity forming face 13a. However, the molding tool 13 may be inverted upside-down to form the cavity forming face 13a on a bottom part 13e and to form the protrusions 13c corresponding to the dicing lines 7b on the cavity forming face 13a of the bottom part 13e.

Here, a molding resin 14, as shown in FIG. 8A, to be used in the block-molding operation is exemplified by a thermoset epoxy resin or the like, of which the block-molded portion 8 is formed and is diced and individualized to form the sealing portion 6.

On the other hand, the tape substrate 2 is preferred to consider the thinness of the CSP 9 and the adhesion, the heat resistance and the hygroscopic resistance to the molding resin 14 and is exemplified by a wiring substrate of a thin film made of a flexible polyimide tape or the like but may use an epoxy resin.

In the tape substrate 2, as shown in FIGS. 3A and 3B, there are formed on the chip supporting face 2a a plurality of bump lands 2e made of a copper foil, the connection terminals 2c and wiring portions 2d, of which the bump lands 2e and the corresponding connection terminals 2c are connected through the wiring portions 2d.

Here, to the back face 2b of the tape substrate 2, there are exposed the plurality of individual bump lands 2e, at which the solder balls 3 are individually arranged.

As shown in FIG. 2, on the other hand, the semiconductor chip 1 is made of silicon, for example, and a semiconductor integrated circuit is formed over a principal face 1b of the semiconductor chip 1 whereas the plurality of pads 1a or the surface electrodes are formed on the peripheral edge portion of the principal face 1b.

Moreover, the semiconductor chip 1 is fixed on the almost central portion of the chip supporting face 2a of the tape substrate 2 by a die-bonding material 5 or an insulating epoxy resin (e.g., an inconductive thermoset or thermoplastic adhesive).

On the other hand, the wires 4 to be connected by the wire-bonding method are exemplified by gold wires or aluminum wires and connect the pads 1a of the semiconductor chip 1 and the corresponding connection terminals 2c of the tape substrate 2.

Moreover, the plurality of solder balls 3 or the external terminals connected conductively with the connection terminals 2c of the tape substrate 2 are disposed in the matrix arrangement on the back face 2b of the tape substrate 2 except its central portion. Therefore, the pads 1a of the semiconductor chip 1 and the solder balls 3 or the corresponding external terminals are connected through the wires 4, the connection terminals 2c, the wiring portions 2d and the bump lands 2e.

Next, a method of manufacturing the CSP 9 or the semiconductor device of this embodiment will be described with reference to the process flow chart shown in FIG. 4.

Here, the method of manufacturing the CSP 9 of this embodiment uses the film-shaped tape substrate 2 of the thin film as the chip supporting substrate. The multi-device substrate 7, in which the plurality of tape substrates 2 are formed and connected in the matrix arrangement, as shown in FIG. 5, are used and resin-molded to cover the plurality of divided and formed device areas 7a of the same size on the multi-device substrate 7 altogether and are then diced and individualized to manufacture the CSP 9.

First of all, the frame carrier is prepared at Step S1 of FIG. 4.

Here is prepared the frame carrier 11 which includes: the multi-device substrate 7 having a plurality of (or nine in this embodiment) tape substrates 2 capable of supporting the semiconductor chip 1 and the nine device areas 7a divided and formed to correspond to the individual tape substrates 2; and the frame member 11a for supporting the multi-device substrates 7.

At this time, there is prepared a flexible, tape-shaped multi-string base substrate 12 having the plurality of multi-device substrates 7 in which the tape substrates 2 of the thin film or the plurality of (or nine in this embodiment) device areas 7a are connected in the matrix arrangement of 3 rows×3 columns.

Moreover, the multi-string base substrate 12 is cut and separated to the individual multi-device substrates 7, as shown in FIG. 5, and these multi-device substrates 7 are adhered to the frame member 11a made of copper or the like to form the frame carrier 11.

Specifically, the frame carrier 11 includes the plurality of multi-device substrates 7, and the frame member 11a to which the multi-device substrates 7 are applied.

Here, the frame carrier 11 may be prepared by assembling it in the semiconductor manufacturing process by the aforementioned forming method or by delivering the frame carrier 11 which has been formed in advance at the outside.

Here will be described the method of manufacturing the multi-string base substrate 12 having the plurality of device areas 7a.

First of all, the base material of the multi-string base substrate 12 is made of an insulating resin such as polyimide or epoxy, and an adhesive is applied to the base material. Here, the multi-string base substrate 12 may be fused without employing the adhesive.

After this, at the bump land arranging portions of the individual device areas 7a, a punching die or a laser or the like is used to form through holes 2f (as referred to FIG. 2), to which a conductor such as a copper foil is adhered.

After the conductor was adhered to the base material, the through holes 2f may be formed by using the punching die or the laser.

After this, the wiring pattern is formed by an etching method. As a result, there are formed the bump lands 2e, the wiring portions 2d and the connection terminals 2c.

In order to avoid any contact between the wiring portions 2b and the connection terminals 2c, an insulating layer (of a solder resist film, for example) may be formed over the wiring portions 2b and the connection terminals 2c of the area, on which the semiconductor chip 1 is mounted.

Moreover, the connection terminals 2c are coated (with Ni—Au, Ni—Pd—Au, Ni—Pd or Ni—Sn for example) for a wire-bonding to form the multi-string base substrate 12, as shown in FIG. 5.

After this, the multi-string base substrate 12 is cut and separated into the individual multi-device substrates 7, which are then adhered to the predetermined portions of the frame member 11a by means of an epoxy adhesive or the like to complete the frame carrier 11.

Here, the carrying property and the handling property at the assembling step can be improved by assembling the CSP 9 using the frame carrier 11.

After this, there is performed the die-bonding of Step S2 of FIG. 4.

At this time, there is prepared the semiconductor chip 1 which has the desired semiconductor integrated circuit formed on the principal face 1b. The die-bonding material 5 shown in FIG. 2 is applied to the device areas 7a of the multi-device substrates 7, as shown in FIG. 5, of the frame carrier 11 to mount the semiconductor chip 1, as shown in FIG. 6.

Here, the die-bonding material 5 is exemplified by an insulating adhesive (e.g., an inconductive thermoset or thermoplastic adhesive) to joint the die-bonding material 5 and the back face 1c of the semiconductor chip 1.

After this, there is performed the wire-bonding of Step S3.

Here, as shown in FIG. 2, the pads 1a or the surface electrodes disposed on the peripheral edge portion of the principal face 1b of the semiconductor chip 1 and the corresponding connection terminals 2c (or the electrodes) formed on the tape substrates 2 are connected by the wire-bonding method using the wires 4 (or the conductive members) such as gold wires as shown in FIG. 7.

After this wire-bonding, there is performed the block-molding of Step S4.

First of all at this time, as shown in FIG. 8A, there is prepared the molding tool 13 which is provided with: the cavity 13b for covering the plurality of device areas 7a shown in FIG. 5 altogether on the side of the chip supporting face 2a of the multi-device substrates 7; and the lattice-shaped protrusions 13c corresponding to the dicing lines 7b shown in FIG. 5 and formed on the cavity forming face 13a for forming the cavity 13b.

Here, this embodiment corresponds to the case using the transfer molding mold tool 13 including the top part 13d and the bottom part 13e, of which the top part 13d is provided with the cavity forming face 13a having the lattice-shaped protrusions 13c corresponding to the dicing lines 7b for forming the cavity 13b.

When the block-molded portion 8 which is a block-sealed portion shown in FIG. 10 is to be formed by the block-molding operation, it is preferable for achieving a sufficient warpage reducing effect that the depth of the grooves 8a to be formed in the portions corresponding to the dicing lines 7b in the block-molded portion 8 is made one half or more of the thickness of the block-molded portion 8.

Therefore, it is also preferred that the protrusions 13c to be formed on the cavity forming face 13a of the top part 13d of the molding tool 13 is made one half or more of the depth of the cavity 13b.

However, the height of the protrusions should not be limited to one half or more of the depth of the cavity 13b but may be made less.

After this, the frame carrier 11 is so set that the semiconductor chip 1 and the wires 4 are arranged in the cavity 13b between the top part 13d and the bottom part 13e of the molding tool 13, as shown in FIG. 8A, and the plurality of (or nine in this embodiment) device areas 7a shown in FIG. 5 are covered altogether with the one cavity 13b.

In this state, the molding resin 14 is fed to fill the cavity 13b thereby to resin-seal the semiconductor chip 1 and the wires 4.

Here, the molding resin 14 to be used is exemplified by a thermoset epoxy resin.

After this, the molding resin 14 is set to form the block-molded portion 8, as shown in FIG. 8B. At this time, in the block-molded portion 8 and at the portions of corresponding to the dicing lines 7b on the surface (as referred to FIG. 5), the grooves 8a are formed by the protrusions 13c of the molding tool 13.

With these grooves 8a thus formed, therefore, the block-molded portion 8 at the resin setting time is released from the warpage, as might otherwise be caused by resin shrinkages 17, so that the warpage of the block-molded portion 8 in the frame carrier 11 is reduced (or relaxed).

Within the individual device areas 7a surrounded by the grooves 8a, on the other hand, the warpage is caused by the resin shrinkages at the resin setting time, but the individual device areas 7a are narrower than the block-molded portion 8 so that the individual device areas 7a are free from such warpage as to degrade the assembly very much.

Thus, the block-molding operation is ended.

After the molding operation, runners 15 are formed of the molding resin 14, as shown in FIG. 9, so that they are folded at the joint portions to the block-molded portion 8 and are removed.

After this, the bump mounting operation, as shown at Step S5 of FIG. 4, is performed to attach the solder balls (or the bump electrodes) 3 or the external terminals to the back face 2b of each of the tape substrates 2, as shown in FIG. 2, of the multi-device substrates 7.

At this time, the solder balls 3 are melted by an infrared reflow, for example, and are attached to the bump lands 2e of the tape substrates 2 shown in FIG. 3.

Here, these attachments of the solder balls 3 may be done before the dicing or after the dicing after the block-molding operation.

After this, there is performed the dicing operation shown at Step S6.

Here, the multi-device substrate 7 and the block-molded portion 8 are divided and individualized along the grooves 8a formed in the block-molded portion 8 at the unit of the device areas 7a shown in FIG. 5.

At this time, as shown in FIG. 11A, the block-molded portion 8 is fixed on the dicing stage by adhering a dicing tape 16 to the surface of the block-molded portion 8. After this, the block-molded portion 8 is cut (or individualized) by the full dicing operation using a blade 10 or a dicing cutting blade, as shown in FIG. 11b.

Thus, the CSP 9 is manufactured.

Here at the dicing time, the tape substrates 2 can be prevented from separating by inserting the blade 10 to cut from the side of the tape substrates 2.

According to the method of manufacturing the semiconductor device (or the CSP 9) of this embodiment, there can be attained the following effects.

By the block-molding method using the molding tool 13 having the protrusions 13c on the cavity forming face 13a, more specifically, the grooves 8a are formed in the surface of the block-molded portion 8 when this portion 8 is formed. Therefore, the tensile deformation of the surface of the block-molded portion 8 at the setting/shrinking time of the molding resin 14 can be reduced (or relaxed) by the grooves 8a, as shown in FIG. 8B, to reduce the resin shrinkages 17 thereby reduce the warpage of the block-molded portion 8 after the resin was set.

As a result, it is possible to improve the assembly at the manufacture step after the molding operation. For example, it is possible to prevent degradations in the mountability of the solder balls 3 at the assembling step after the molding operation and in the cutting property of the tape substrates 2 (or the multi-device substrate 7).

As a result, the yield of the CSP 9 can be improved to lower the cost. Moreover, the assembly at the manufacturing step after the molding operation can be improved to reduce the occurrence of troubles in the quality thereby to improve the quality of the CSP 9.

Here in this embodiment, when the block-molded portion 8 is to be formed, the grooves 8a are formed at portions corresponding to the dicing lines 7b on the surface of that portion 8 by the block molding operation using the molding tool 13 which has the lattice-shaped protrusions 13c formed on the cavity forming face 13a to correspond to the dicing lines 7b.

As a result, the tensile deformation of the surface of the block-molded portion 8 at the setting/shrinking time of the molding resin 14 can be reduced (or relaxed) by the grooves 8a thereby to reduce the resin shrinkages 17 shown in FIG. 8B.

Therefore, it is possible to reduce the warpage of the block-molded portion 8 after the resin was set.

Moreover, the grooves 8a are formed at the portions corresponding to the dicing lines 7b in the block-molded portion 8 so that the stress to be applied to the block-molded portion 8, although warped to some extent, by the pushing force of the blade 10 at the dicing step after the molding operation can be concentrated on the grooves 8a corresponding to the dicing lines 7b.

Therefore, it is possible to relax the stress to be applied to the surface of the block-molded portion 8 and to form the cracks, if any, in the grooves 8a corresponding to the dicing lines 7b. As a result, it is possible to prevent the cracks from being formed in the sealing portion of each CSP 9.

By making the depth of the grooves 8a formed in the portions corresponding to the dicing lines 7b of the block-molded portion 8, about one half or less of the thickness of the block-molded portion 8, on the other hand, the flow of the molding resin 14 in the cavity 13b at the molding time is not obstructed so that the warpage of the block-molded portion 8 can be reduced.

Although our invention has been specifically described on the basis of its embodiment, it should not be limited thereto but can naturally be modified in various manners without departing the gist thereof.

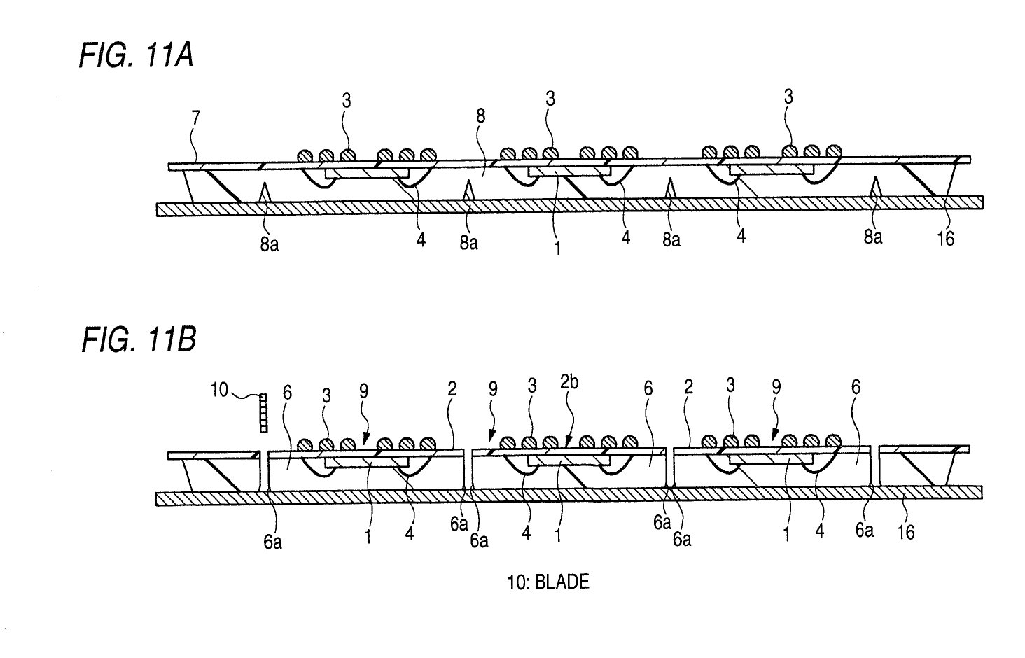

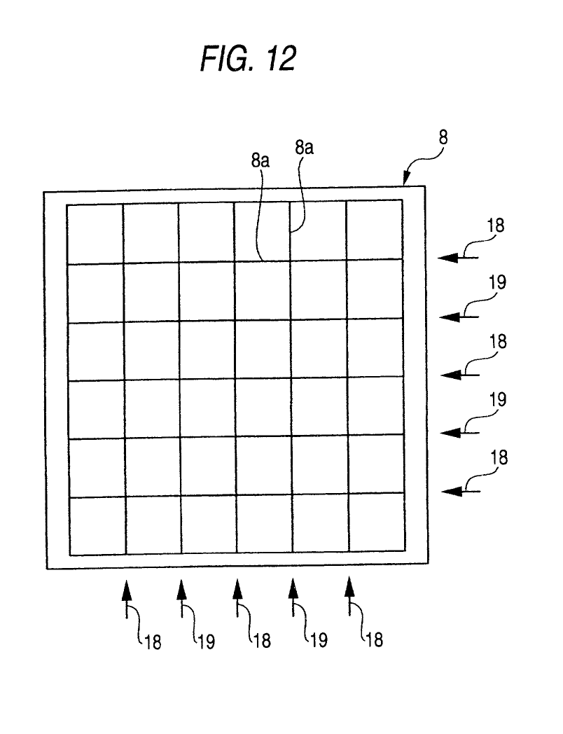

For example, the embodiment has been described on the case in which the grooves 8a are formed at the portions corresponding to the individual dicing lines 7b for the plurality of device areas 7a (or the CSP 9) of the same size in the block-molded portion 8. As shown as a modification in FIG. 12, however, the grooves may be formed at the portions corresponding to the dicing lines 7b for a plurality of kinds of CSP sizes.

By performing the block-molding operation using the molding tool 13 having the lattice-shaped protrusions 13c corresponding to the dicing lines 7b for the plurality of kinds of CSP sizes in the cavity forming face 13a, more specifically, it is possible to form the block-molded portion 8 which has the grooves 8a formed by the protrusions 13c at the portions corresponding to the dicing lines 7b on the surface for the plurality of kinds of CSP sizes.

In the block-molded portion 8 of a modification shown in FIG. 12, of the grooves 8a, for example, the groove 8a for the CSP 9 having a size of 6 mm×6 mm is provided for a groove 18 for an A-size CSP, and the groove 8a for the CSP 9 having a size of 12 mm×12 mm is provided for a groove 19 for a B-size CSP, and the dicing operations are performed along the grooves 8a in accordance with the sizes of the individual CSPs 9.

In the block-molded portion 8, therefore, there can be formed the grooves 8a (i.e., the grooves 18 for the A-size CSP and the grooves 19 for the B-size CSP in FIG. 12) corresponding to the individual dicing lines 7b of the plurality of kinds of CSP sizes so that one molding tool 13 can be used to cope with the various sizes of the CSPs 9. As a result, the molding tool 13 can be made common independently of the sizes of the CSPs 9.

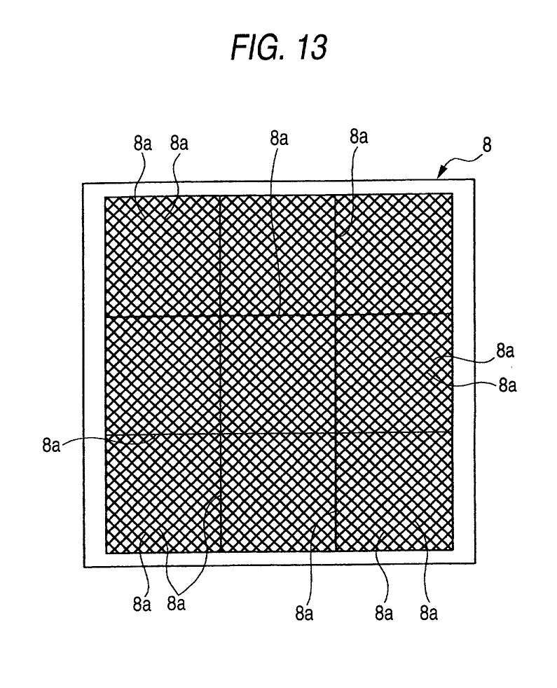

On the other hand, the foregoing embodiment has been described on the case in which the grooves 8a in the block-molded portion 8 are formed only at the portions corresponding to the dicing lines 7b. However, the grooves 8a should not be limited only to the portions corresponding to the dicing lines 7b (as referred to FIG. 5) but may be additionally formed in the inner area, as exemplified by the block-molded portion 8 of a modification of FIG. 13.

Specifically, the block-molding operation is performed by using the molding tool 13 which is provided with the dicing lines 7b on the cavity forming face 13a and the plurality of corresponding protrusions 13c around the dicing lines 7b, thereby to form the block-molded portion 8 in which the grooves 8a are formed not only at the portions corresponding to the dicing lines 7b on the surface but also their inner areas.

In the block-molded portion 8 of the modification shown in FIG. 13, the net-shaped (or mesh-shaped) grooves 8a are formed in the inner area of the lattice-shaped grooves 8a at the portions corresponding to the dicing lines 7b.

When the block-molded portion 8 is formed, therefore, the grooves 8a are formed not only at the portions corresponding to the dicing lines 7b on the surface but also in the inner area. Therefore, the tensile deformation at the setting/shrinking time of the molding resin 14 can be reduced not only by the grooves 8a of the dicing lines 7b but also by the grooves 8a formed in the inner area, thereby to reduce the warpage of the block-molded portion 8 more.

On the other hand, the depth of the grooves to be formed in the block-molded portion 8 should not be limited to the one kind but may be made different at the portions corresponding to the dicing lines 7b and at the remaining portions, for example, and the grooves 8a of a plurality of kinds of depths may be formed at their respective forming portions of the grooves 8a.

By the block-molding operation using the molding tool 13 which is provided with the dicing lines 7b in the cavity forming face 13a and the plurality of kinds of corresponding protrusions 13c around the dicing lines 7b, especially, by the block-molding the operation using molding tool 13 which the protrusion 13c corresponding to the dicing lines 7b are made higher than the protrusions 13c around the former, more specifically, the grooves 8a at the portions corresponding to the dicing lines 7b in the surface of the block-molded portion 8 can be made deeper than the grooves 8a in the inner area of those portions.

However, the grooves 8a, as formed at the portions other than those corresponding to the dicing lines 7b, i.e., in the inner area of the dicing lines 7b, are made so deep as to fail to reach the wire loop which is formed of the wires 4.

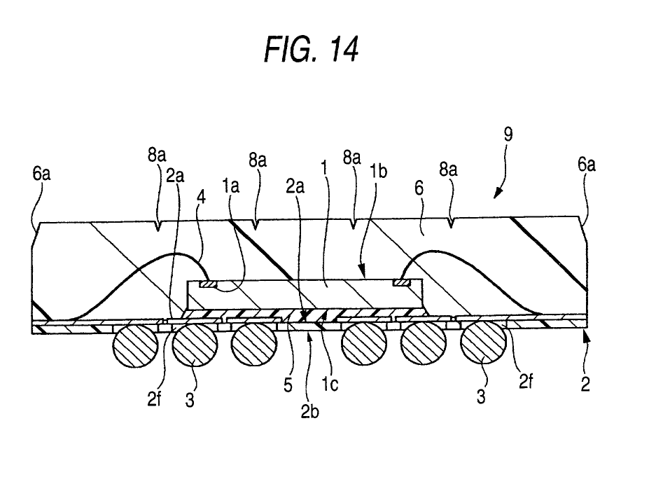

In the block-molded portion 8 of a modification shown in FIG. 14, therefore, the grooves 8a (or the slopes 6a) at the portions corresponding to the dicing lines 7b and the grooves 8a in the inner area are given different depths. The grooves 8a (or the slopes 6a) corresponding to the dicing lines 7b are made deeper than the grooves 8a in the inner area, and these grooves 8a formed in the inner area are made so deep as not to reach the wire loop.

In the modification of FIG. 14, for example, if the block-molded portion 8 is given a thickness of about 0.6 mm, the slopes 6a have a depth (or length) of about 0.3 mm, and the grooves 8a to be formed in the aforementioned inner area has a depth of about 50 to 100 microns.

Therefore, the depth of the grooves 8a at the portions corresponding to the dicing lines 7b are made deeper so that the stress to be applied to the blade 10 at the dicing time can be further concentrated at the grooves 8a corresponding to the dicing lines 7b. As a result, the stress to be applied to the surface of the block-molded portion 8 can be further relaxed.

Therefore, it is possible to prevent the sealing portion 6 of each CSP 9 more from being cracked.

By making the grooves 8a to be formed in the aforementioned inner area of the surface of the block-molded portion 8, so deep as not to reach the wire loop made of the wires, on the other hand, the wires 4 can be reliably rein-sealed and prevented from being exposed.

As a result, it is possible to improve the quality of the CSP 9.

On the other hand, the grooves 8a to be formed in the surface of the block-molded portion 8 may be provided in plurality independently of the dicing lines 7b.

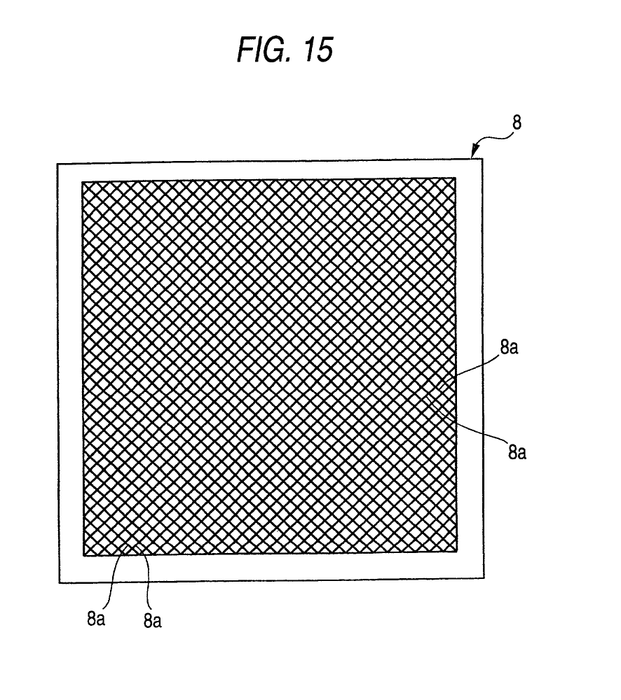

Therefore, the block-molded portion 8 of a modification shown in FIG. 15 is formed by performing the block-molding operation using the molding tool 13 which is provided with the plurality of protrusions 13c on the cavity forming face 13a. This modification is exemplified by the case in which the plurality of grooves are formed in the surface of the block-molded portion 8 independently of the dicing lines 7b in a direction different from that of the dicing lines 7b, so that a multiplicity of grooves 8a are formed in a net shape (or a mesh shape) at a small pitch.

Therefore, the multiple grooves 8a are formed in the surface of the block-molded portion 8 so that the warpage of the block-molded portion 8 can be reduced. In this case, moreover, the plurality of protrusions 13c can be formed in the molding tool 13 independently of the dicing lines 7b so that the protrusions 13c can be substantially homogeneously dispersed in the cavity forming face 13a of the molding tool 13 irrespective of the size of the CSP 9.

Therefore, one molding tool 13 can be used to cope with the various sizes of the CSPs 9 so that it can be made common independently of the sizes of the CSPs 9.

By performing the block-molding operation using the molding tool 13 which is provided with the multiple protrusions 13c on the cavity forming face 13a, on the other hand, the multiple grooves 8a are formed in the surface of the block-molded portion 8 when this portion 8 is formed. As a result, the plurality of grooves 8a can be formed in the surface of the sealing portion 6 of the individualized CSP 9.

Therefore, it is also possible to reduce the warpage of each CSP 9.

On the other hand, the aforementioned embodiment has been described on the case using the multi-device substrate 7 in which the device areas 7a are arranged in the matrix of 3 rows×3 columns. When there is used a rectangular multi-device substrate 7 having a matrix arrangement of 3 rows×5 columns (or 5 rows×3 columns), for example, it is estimated, as in a modification shown in FIG. 16, that the block-molded portion 8 is made rectangular to have a larger warpage in the length direction.

By performing the block-molding operation using the molding tool 13 in which the lattice-shaped protrusions 13c having two kinds of heights (i.e., the protrusions 13c parallel to the length direction and the higher protrusions 13c parallel to the width direction) are formed on the rectangular cavity forming face 13a, therefore, the grooves 8a (as referred to FIG. 17B) parallel to the width direction of the rectangular block-molded portion 8 can be formed at the portions corresponding to the dicing lines 7b in the surface of the rectangular block-molded portion 8 can be made deeper than the grooves 8a (as referred to FIG. 17A) in parallel to the length direction.

Even in the case of the rectangular block-molded portion 8 having the surface of a different aspect ratio, therefore, it is possible to reduce the warpage of the block-molded portion 8 easy to warp in the length direction.

On the other hand, the aforementioned embodiment has been described on the case in which the CSP 9 is manufactured by using such a frame carrier 11 that the multi-device substrate 7 having the plurality of device areas 7a formed in the matrix arrangement is attached to the frame member 11a. However, the frame carrier 11 need not always be used, but the block-molding operation may be performed by using only the multi-device substrate 7.

In this case, the multi-string base substrate 12 is enabled to take the place of the multi-device substrate 7 having the frame carrier 11 by giving the function as the carrier to the multi-string base substrate 12 itself such that an opening may be formed in the peripheral portion of the multi-string base substrate 12.

On the other hand, the aforementioned embodiment has been described on the case in which the grooves 8a are formed in the block-molded portion 8 at the molding step using the molding tool 13 having the protrusions 13c on the cavity forming face 13a. However, the resin-sealing may be performed by the block-molding operation to set the molding region 14 thereby to form the block-molded portion 8, and the grooves 8a may then be formed at the desired portions of the surface of the block-molded portion 8.

At this time, it is preferred that the grooves 8a are formed by the dicing blade 10 before the solder balls 3 (or the bump electrodes) or the external terminals are attached to the tape substrates 2.

By the dicing apparatus having the blade 10, more specifically, the grooves 8a are formed in the block-molded portion 8 after the block-molding operation and before the ball attachments.

According to this method, the warpage occurs in the block-molded portion 8 while being accompanied by the stress to be caused by the resin shrinkages at the resin setting time. By forming the grooves before the subsequent step of mounting the solder balls 3 and the dicing step to release that stress thereby to reduce the warpage, however, it is possible to achieve the effects similar to those of the case of the aforementioned embodiments.

On the other hand, the aforementioned embodiment has been described on the case in which the block-molding operation is performed by the transfer molding operation using the molding tool 13. However, the block-molding operation may resort to the potting type which is effected by applying a potting resin.

Specifically, the potting resin is applied to cover the plurality of device areas 7a of the multi-device substrate 7 altogether on the side of the chip supporting face 2a to seal the semiconductor chip 1 with the potting resin thereby to form the block-molded portion 8, and the grooves 8a are then formed in the surface of the block-molded portion 8.

On the other hand, the aforementioned embodiment has been described on the case in which the tape substrates 2 is made of a substrate of a thin film of polyimide. However, the tape substrates 2 may be made of a material other than polyimide.

Moreover, the aforementioned embodiment has been described on the case in which the semiconductor device is the CSP 9. This semiconductor device may be another one such as the BGA other than the CSP 9 if it is of the type in which the semiconductor device is diced and individualized after it was block-molded by using the multi-device substrate 7 having the plurality of tape substrates 2.

Here will be briefly described the effects which are obtained by the representative ones of the invention disclosed herein.

(1) By performing the block-molding method using the molding tool having the protrusions formed on the cavity forming face, the grooves are formed in the surface of the block-sealed portion. Therefore, the tensile stress of the surface and the resulting deformation at the setting shrinkage of the molding resin can be reduced to reduce the warpage of the block-sealed portion after the resin was set. Therefore, it is possible to improve the assembly at the manufacturing step after the molding operation. As a result, the yield of the semiconductor device can be improved to lower the cost.

(2) The assembly at the manufacturing step after the molding operation can be improved to reduce the occurrence of troubles in the quality thereby to improve the quality of the semiconductor device.

(3) By performing the block-molding method using the molding tool having the plurality of protrusions on the cavity forming face, the warpage of the block-sealed portion can be reduced. In this case, the plurality of protrusions can be formed independently of the dicing lines so that the molding tool can be made common independently of the size of the semiconductor device.

(4) By performing the block-molding method using the molding tool having the plurality of protrusions on the cavity forming face, the plurality of grooves can be formed in the surface of the sealed portion of the individualized semiconductor device. As a result, it is possible to reduce the warpage in each semiconductor device.

(5) The grooves are formed in the portions corresponding to the dicing lines in the block-sealed portion so that the stress to be applied to the block-sealed portion by the pushing force of the blade at the dicing step after the molding operation can be concentrated at the grooves corresponding to the dicing lines. Therefore, it is possible to relax the stress to be applied to the surface of the block-sealed portion and to the cracks, if any, in the grooves corresponding to the dicing lines. As a result, it is possible to prevent the sealed portion of each semiconductor substrate from being cracked.

(6) By performing the block-molding operation using the molding tool which has the lattice-shaped protrusions corresponding to the dicing lines of the plurality of semiconductor device sizes on the cavity forming face, the grooves corresponding to the dicing lines of the plurality of individual semiconductor device sizes can be formed in the block-sealed portion. Therefore, one molding tool can be used to match the various sizes of the semiconductor devices so that the molding tool can be made common independently of the sizes of the semiconductor devices.

(7) By performing the block-molding operation using the molding tool having the lattice-shaped protrusions of two kinds of heights on the rectangular cavity forming face, the grooves parallel to the width direction of the rectangle can be formed deeper at the portions corresponding to the rectangular dicing lines of the block-sealed portion than the grooves parallel to the length direction. Even in the case of the rectangular block-sealed portion, therefore, it is possible to reduce the warpage of the easily warping block-sealed portion in the length direction.

1. A method of manufacturing a resin-sealed type semiconductor device, comprising:
the step of preparing a chip supporting substrate having a plurality of device areas;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering said plurality of device areas altogether on the chip supporting face side of said chip supporting substrate and protrusions on a cavity forming face for forming said cavity;
the step of resin-sealing said semiconductor chip by feeding a molding resin to said cavity with said plurality of device areas being covered altogether with said cavity, and forming a block-sealed portion having grooves formed in the surface by said protrusions; and
the step of dividing said chip supporting substrate and said block-sealed portion at the unit of said device areas.

2. A method of manufacturing a resin-sealed type semiconductor device, comprising:
the step of preparing a frame carrier including: a chip supporting substrate having a plurality of device areas; and a frame member for supporting said chip supporting substrate;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering said plurality of device areas altogether on the chip supporting face side of said chip supporting substrate and protrusions on a cavity forming face for forming said cavity;
the step of resin-sealing said semiconductor chip by feeding a molding resin to said cavity with said plurality of device areas being covered altogether with said cavity, and forming a block-sealed portion having grooves formed in the surface by said protrusions; and
the step of dividing and individualizing said chip supporting substrate and said block-sealed portion at the unit of said device areas.

3. A method of manufacturing a resin-sealed type semiconductor device, comprising:
the step of preparing a chip supporting substrate having a plurality of device areas;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering said plurality of device areas altogether on the chip supporting face side of said chip supporting substrate and a plurality of protrusions on a cavity forming face for forming said cavity;
the step of resin-sealing said semiconductor chip by feeding a molding resin to said cavity with said plurality of device areas being covered altogether with said plurality of cavity, and forming a block-sealed portion having a plurality of grooves formed in the surface by said protrusions; and
the step of dividing said chip supporting substrate and said block-sealed portion at the unit of said device areas to assemble a semiconductor device having said plurality of grooves formed in the surface of said sealed portion.

4. A semiconductor device manufacturing method according to claim 1,
wherein by using the molding tool having said plurality of protrusions formed in a net shape on said cavity forming face, with said plurality of device areas being covered altogether with said cavity, the molding resin is fed to said cavity to resin-seal said semiconductor chip, and
wherein after said block-sealed portion having said grooves formed in the net shape in the surface by said protrusions was formed, said chip supporting substrate and said block-sealed portion are divided at the unit of said device areas to assemble the semiconductor device having said grooves formed in the net shape in the surface of said sealed portion.

5. A method of manufacturing a resin-sealed type semiconductor device, comprising:
the step of preparing a chip supporting substrate having a plurality of device areas;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering said plurality of device areas altogether on the chip supporting face side of said chip supporting substrate and lattice-shaped protrusions corresponding to dicing lines on a cavity forming face for forming said cavity;
the step of resin-sealing said semiconductor chip by feeding a molding resin to said cavity with said plurality of device areas being covered altogether with said cavity, and forming a block-sealed portion having grooves at the portions corresponding to the dicing lines of the surface formed by said protrusions; and
the step of dividing said chip supporting substrate and said block-sealed portion along said grooves at the unit of said device areas.

6. A method of manufacturing a resin-sealed type semiconductor device, comprising:
the step of preparing a chip supporting substrate having a plurality of device areas;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering said plurality of device areas altogether on the chip supporting face side of said chip supporting substrate and dicing lines on a cavity forming face for forming said cavity and a plurality of corresponding protrusions around said dicing lines;
the step of resin-sealing said semiconductor chip by feeding a molding resin to said cavity with said plurality of device areas being covered altogether with said cavity, and forming a block-sealed portion having grooves formed in the surface at the portions corresponding to the dicing lines and in the inner area by said protrusions; and
the step of dividing said chip supporting substrate and said block-sealed portion along said grooves corresponding to said dicing lines at the unit of said device areas.

7. A method of manufacturing a resin-sealed type semiconductor device, comprising:
the step of preparing a frame carrier including: a chip supporting substrate having a plurality of device areas; and a frame member for supporting said chip supporting substrate;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering said plurality of device areas altogether on the chip supporting face side of said chip supporting substrate and lattice-shaped protrusions corresponding to dicing lines on a cavity forming face for forming said cavity;
the step of resin-sealing said semiconductor chip by feeding a molding resin to said cavity with said plurality of device areas being covered altogether with said cavity, and forming a block-sealed portion having grooves formed at portions corresponding to the dicing lines in the surface by said protrusions; and
the step of dividing and individualizing said chip supporting substrate and said block-sealed portion along said grooves at the unit of said device areas.

8. A method of manufacturing a resin-sealed type semiconductor device, comprising:
the step of preparing a chip supporting substrate having a plurality of device areas;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering said plurality of device areas altogether on the chip supporting face side of said chip supporting substrate and lattice-shaped protrusions corresponding to dicing lines of a plurality of kinds of semiconductor chip sizes on a cavity forming face for forming said cavity;
the step of resin-sealing said semiconductor chip by feeding a molding resin to said cavity with said plurality of device areas being covered altogether with said cavity, and forming a block-sealed portion having grooves at the portions corresponding to the dicing lines, as corresponding to the plurality of kinds of semiconductor device sizes, of the surface and formed in the surface by said protrusions; and
the step of dividing said chip supporting substrate and said block-sealed portion along said grooves at the portions corresponding to the dicing lines corresponding to the individual semiconductor device sizes at the unit of said device areas.

9. A method of manufacturing a resin-sealed type semiconductor device, comprising:
the step of preparing a chip supporting substrate having a plurality of device areas;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering said plurality of device areas altogether on the chip supporting face side of said chip supporting substrate and a plurality of protrusions on a cavity forming face for forming said cavity;
the step of resin-sealing said semiconductor chip by feeding a molding resin to said cavity with said plurality of device areas being covered altogether with said cavity, and forming a block-sealed portion having a plurality of grooves formed in a direction different from that of the dicing lines in the surface by said protrusions; and
the step of dividing said chip supporting substrate and said block-sealed portion at the unit of said device areas to assemble a semiconductor device having said plurality grooves formed in the direction different from that of the dicing lines in the surface of said sealed portion.

10. A method of manufacturing a resin-sealed type semiconductor device, comprising:
the step of preparing a chip supporting substrate having a plurality of device areas;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering said plurality of device areas altogether on the chip supporting face side of said chip supporting substrate and protrusions of a plurality of kinds of heights on a cavity forming face for forming said cavity;
the step of resin-sealing said semiconductor chip by feeding a molding resin to said cavity with said plurality of device areas being covered altogether with said cavity, and forming a block-sealed portion having grooves of depths different at respective portions formed in the surface by said protrusions; and
the step of dividing said chip supporting substrate and said block-sealed portion at the unit of said device areas to assemble a semiconductor device having said plurality of grooves formed in the surface of said sealed portion.

11. A method of manufacturing a resin-sealed type semiconductor device, comprising:
the step of preparing a chip supporting substrate having a plurality of device areas;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering the plurality of device areas altogether on the chip supporting face side of said chip supporting substrate and dicing lines on a cavity forming face for forming said cavity and the corresponding protrusions of a plurality of kinds of heights around said dicing lines;
the step of resin-sealing said semiconductor chip by feeding a molding resin to said cavity with said plurality of device areas being covered altogether with said cavity, and forming a block-sealed portion having grooves formed in the surface at the portions corresponding to the dicing lines and in the inner area by said protrusions such that the grooves at the portions corresponding to said dicing lines are made deeper than the grooves in said inner area; and
the step of dividing said chip supporting substrate and said block-sealed portion along said grooves corresponding to said dicing lines at the unit of said device areas, and assembling a semiconductor device having the plurality of said grooves in the surface of the sealed portion.

12. A semiconductor device manufacturing method according to claim 11,
wherein the depth of the grooves formed at the portions corresponding to said dicing lines of said block-sealed portion is made as deep as about one half of the thickness of said block-sealed portion.

13. A semiconductor device manufacturing method according to claim 11,
wherein the grooves formed in said inner area of the surface of said block-sealed portion are made so deep as not to reach a wire loop formed of wires or said conductive members.

14. A method of manufacturing a resin-sealed type semiconductor device, comprising:
the step of preparing a chip supporting substrate having a plurality of device areas;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering said plurality of device areas altogether on the chip supporting face side of said chip supporting substrate and lattice-shaped protrusions of two kinds of heights on a rectangular cavity forming face for forming said cavity;
the step of resin-sealing said semiconductor chip by feeding a molding resin to said cavity with said plurality of device areas being covered altogether with said cavity, and forming a block-sealed portion having grooves at the portions corresponding to the dicing lines of the rectangular surface and formed in the surface by said protrusions such that the grooves parallel to the width direction are made deeper than the grooves parallel to the length direction; and
the step of dividing said chip supporting substrate and said block-sealed portion along grooves of two kinds of depths at the unit of said device areas.

15. A method of manufacturing a resin-sealed type semiconductor device, comprising:
the step of preparing a chip supporting substrate having a plurality of device areas;
the step of mounting a semiconductor chip on said device areas;
the step of connecting the surface electrode of said semiconductor chip and the corresponding electrode of said chip supporting substrate through conductive members;
the step of covering said plurality of device areas altogether with a cavity, by using a molding tool which is provided with said cavity for covering said plurality of device areas altogether on the chip supporting face side of said chip supporting substrate;
the step of forming a block-sealed portion by feeding a molding resin with said plurality of device areas being covered altogether with said cavity, to resin-seal said semiconductor chip;
the step of forming grooves in the surface of said block-sealed portion after said molding resin was set to form said block-sealed portion; and
the step of dividing said chip supporting substrate and said block-sealed portion at the unit of said device areas.

16. A semiconductor device manufacturing method according to claim 15,
wherein said grooves are formed in the surface of said block-sealed portion by a dicing blade after said molding resin was set to form said block-sealed portion and before the bump electrodes or the external terminals are attached to said chip supporting substrate.

17. A method of manufacturing a resin-sealed type semiconductor device, comprising:
the step of preparing a chip supporting substrate having a plurality of device areas;
the step of mounting a semiconductor chip on said device areas;
the step of connecting the surface electrode of said semiconductor chip and the corresponding electrode of said chip supporting substrate through conductive members;
the step of forming a block-sealed portion by resin-sealing said semiconductor chip with a potting resin by applying said potting resin so that a plurality of device areas may be covered altogether on the chip supporting face side of said chip supporting substrate;
the step of forming grooves in the surface of said block-sealed portion after said potting resin was set to form said block-sealed portion; and
the step of dividing said chip supporting substrate and said block-sealed portion at the unit of said device areas.

18. A semiconductor device manufacturing method according to claim 1,
wherein said chip supporting substrate is made of a flexible substrate.
